(19) United States
(12) Patent Application Publication
(10) Pub. No.: US 2013/0076371 A1
(43) Pub. Date: Mar. 28, 2013

(54) ADHESIVE WITH ANISOTROPIC ELECTRICAL CONDUCTIVITY AND METHODS OF PRODUCING AND USING SAME

(71) Applicant: Samuel Buschhorn, Hamburg (DE)

(72) Inventor: Samuel Buschhorn, Hamburg (DE)

(73) Assignee: TuTech Innoovation GmbH, Hamburg (DE)

(21) Appl. No.: 13/581,300

(22) PCT Filed: Feb. 25, 2011
(86) PCT No.: PCT/EP11/52862

§ 371 Date: Dec. 11, 2012

(30) Foreign Application Priority Data
Feb. 26, 2010 (DE) 10 2010 002 447.3

(51) Int. Cl. C09J 9/02; G01R 31/04

(52) U.S. Cl. CPC C09J 9/02; G01R 31/041; Y10S 977/742; B82Y 30/00
USPC 324/538; 156/60; 156/275.5; 252/511; 977/742

(57) ABSTRACT

The invention relates to an electrically conductive adhesive, comprising an adhesively acting, curable and electrically non-conductive matrix material and a phase of electrically conductive carbon nanotubes distributed in the matrix material. According to the invention, the carbon nanotubes are present in a plurality of individual macrostructures, and each macrostructure consists of a plurality of agglomerated carbon nanotubes forming and electrical contact among each other. Another aspect of the invention concerns a method of producing such an electrically conductive adhesive, and a method for electrically conductive bonding of two components and for checking the quality of an adhesive bond formed in such a manner.

The invention relates to an electrically conductive adhesive, comprising an adhesively acting, curable and electrically non-conductive matrix material and a phase of electrically conductive carbon nanotubes distributed in the matrix material. Another aspect of the invention concerns a method of producing such an electrically conductive adhesive, and a method for electrically conductive bonding of two components and for checking the quality of an adhesive bond formed in such a manner.

Electrically conductive adhesives are used in many applications. An example of such use is the adhesive bonding of two printed circuit boards on which a plurality of individual conductive structures are formed and where the aim is to bring these conductive structures into electrical contact with each other across the adhesive gap. Another use involves adhesive bonding of electric components on a printed circuit board and the electrical connection thus formed between electrical contacts on the component with electrical contacts on the printed circuit board.

Many methods and adhesives are basically known for forming such electrical connections. What they have in common is the basic requirement in each case that a reliable electrical connection is formed between the two contacts to be connected, and that this electrical connection is spatially limited in such a way that it is possible for a plurality of such discrete, adjacent electrical connections to be formed with electrical insulation therebetween.

An electrically conductive adhesive and its method of production are known from JP 2001 31 66 55 A. This adhesive contains carbon powder, a binder resin and water and is in the form of a paste. The disadvantage of this adhesive is its very limited ability to cover large areas with a thin layer, to enclose small structures or to penetrate into small structures without causing pockets of trapped air, and the need to use a large proportion of carbon nanopowder as additive in order to provide electrical conductivity with a sufficiently low resistance over the adhesive coating for reliable operation of electrical circuits. Another disadvantage of this prior art adhesive is that complex consecutive steps are needed in the separate production of the single contacts in order to achieve discrete resolution of a plurality of electrical contacts within the adhesive gap and their electrical insulation from each other, as a result of which the method must follow a complicated sequence of steps and takes a long time to form such a plurality of contacts discretely insulated from each other.

An anisotropically conductive adhesive containing finely distributed, conductive particles of gold, nickel, gold-plated nickel, silver or gold-plated polystyrene balls in a film is known from EP 0 748 507 B1. Electrical contacting is achieved in this case by exerting pressure with a punch and by heating the system to a temperature of approximately 150° C. to 230° C., thus allowing electrically conductive structures to press into the film and to come into contact with the particles. The disadvantages of this kind of adhesive film are, firstly, that the particles induce significant mechanical disruption in the overall adhesive and cohesive force provided by the adhesive film, which results not only in the adhesive bond as a whole being unable to absorb any strong mechanical forces, but also in a substantial imperfection being produced by the particles in the region of the electrical contacts, in particular, which can lead to delamination and consequently to contact interruptions when mechanical factors act on the two components to be connected. Another disadvantage of this prior art technology, secondly, is that providing the adhesive in the form of a film with particles finely distributed therein is suitable only for adhesive bonding of substantially flat components and that the field of application is limited as a result. Another disadvantage is that, to obtain an adequate electrical connection with a low electrical resistance, the particles must be present in the film in a concentration which would produce coagulation of the part, and that spacers must be provided on the surface of the particles to prevent such coagulation. These spacers involve substantial production effort and expense, as they have to be applied as a particle coating in an additional production step, and this coating results in an increase in electrical resistance, which reduces the electrical properties of the adhesive on the whole. In many applications, the high processing temperature imposes unacceptable strains on the components to be bonded.

A dry adhesive containing aligned carbon nanotubes (CNT) is known from US 2009/0011232 A1. These nanotubes are present in dry form in parallel axial alignment and are applied to surfaces under the exertion of pressure in order to bond the surfaces. The disadvantage of this dry material is the complex production process involved in creating the parallel carbon nanotube structures, the substantial costs associated with the long carbon nanotubes that are required, and the insufficient adhesion of the dry adhesive for adhesive bonds subjected to heavy loading. Another disadvantage is that, although directional electrical properties are achieved to a certain degree with this kind of dry adhesive, in addition to the directional mechanical properties, anisotropy sufficiently reliable for electrical circuits cannot be achieved in order to electrically connect discrete contacts in electrically insulated form across the adhesive gap.

Finally, an adhesive made of an epoxy resin matrix containing carbon nanotubes and which can be used as an electrically conductive adhesive is known from DE 10 2005 063 403 A1. One disadvantage of this prior art adhesive is the high percentage of carbon nanofibre material that must be introduced into the matrix material to obtain an electrical connection with adequate properties, with the result that the adhesive has a high viscosity, and consequently poor processability and coverage properties, as well as a high level of costs for the adhesive. Another disadvantage is that whenever the electrical properties are sufficient for contacting across the adhesive gap, it is not possible to achieve an anisotropic electrical connection between the adhesive material and electrical contacts which are insulated from each other and spaced apart at discrete intervals.

The object of the invention, in comparison with the aforementioned prior art, is to provide an adhesive which allows the adhesive bond to be produced at low cost, while also allowing a reliable electrical contact to be formed between electrical contacts of two components in a reliable production process, yet also allowing single electrical contacts insulated from one another to be arranged in an array with high spatial resolution. Another aim of the invention is to provide an adhesive which also achieves a mechanically reliable adhesive bond, in addition to meeting the aforementioned requirements in respect of electrical contacting at discrete points and the insulation of these discrete points from each other.

According to the invention, these objects are achieved by the carbon nanotubes being present in a plurality of individual macrostructures, by each macrostructure consisting of a plurality of agglomerated carbon nanotubes forming electrical contact among each other, and by the macrostructures being present in the matrix material preferably in a concentration that is lower than the percolation threshold of the macrostructures within the matrix material.

According to the invention, a matrix material, in particular a monomer, prepolymer or polymer, with electrically conductive carbon nanotubes distributed therein, is used as an adhesive material which characterised in that the carbon nanotubes are not present in a random or intentionally uniform distribution inside the matrix material, but instead are present in an agglomerated form as macrostructures, and in that a plurality of such macrostructures are present in the matrix material. It may be advantageous that the macrostructures are present in the matrix material in a concentration that is lower than the percolation threshold. “Under the percolation threshold” should be understood in this context as the state in which elements which are in their liquid phase touch each other to an extent that it is possible to travel along the elements from one end of the material to the other end, without paths having to be incorporated into the matrix material. A matrix material containing electrically conductive elements is therefore isotropically electrically conductive when the elements are present in or above the percolation threshold. It should be understood, as a basic principle, that percolation can be defined not only for individual elements, such as carbon nanotubes, but also for macroelements composed of a plurality of single elements, such as macrostructures composed of a plurality of carbon nanotubes.

According to the invention, the macrostructures for anisotropically conductive adhesives are present in the matrix material in a concentration below the percolation threshold, i.e., in the absence of any external influence, the macrostructures do not have any inclination or a sufficient percentage of total volume to agglomerate and to form larger contiguous structures of such a kind that larger distances can be bridged.

Due to this composition, the electrically conductive adhesive according to the invention is characterised by a plurality of carbon nanotube agglomerates that form a conductive structure. During the production process for the adhesive according to the invention, or during an adhesive bonding process using the adhesive according to the invention, these agglomerates can be specifically adapted not only in respect of their shape, but also with regard to their dimensions. For example, it is possible by shearing the adhesive twice in succession to produce agglomerates that are spherical in shape, if the directions of shear are at right angles to each other. The more acute the angle between the two directions of shear, the more remote the shape becomes from the spherical shape and the more it adopts an elongate shape. Agglomerates with different shapes can be produced by gyrating the direction of shear. The dimensions of the agglomerates can be influenced by altering, for example, the size of the shear gap in which the adhesive is exposed to shearing. These electrically conductive macrostructures are randomly distributed in an electrically non-conductive matrix material and do not tend to agglomerate. By deploying the macrostructures in a specific form between two contacts to be electrically connected, it is possible with such an adhesive to form a local electrical connection between the contacts. The compact dimensions of the macrostructures results in a high spatial resolution of the electrical contacts, thus allowing very small discrete distances between separate electrical connections which are formed with the electrically conductive adhesive and which must be electrically insulated from each other. The compact dimensions also make it possible, with the aid of the matrix material, to provide a region free of electrically conductive carbon nanotubes between the macrostructures, which ensures reliable electrical insulation and in addition a high adhesive and cohesive transmission of force between the two components to be connected, as a result of which a mechanically reliable adhesive bond can be produced.

According to the invention, the tendency of carbon nanotubes to agglomerate can be specifically utilised to provide a particular conductivity. To this end, the carbon nanotubes are agglomerated only to a particular extent, by limiting the concentration of the macrostructures themselves that are formed in this manner. This prevents the formation of loosely contiguous fractal structures observed in the prior art, which provide conductivity over an indeterminable and unpredictable area. In contrast to the known and natural manifestation of a single, loosely agglomerated structure formed by carbon nanotubes in an array, the adhesive according to the invention is therefore characterised by a plurality of macrostructures separated from each other and having a high concentration of the carbon nanotubes, with matrix regions therebetween which have a highly depleted concentration of carbon nanotubes.

The invention is also advantageous with regard to contact geometry, because in many cases the contact surfaces do not form a uniformly smooth surface at the microscopic level, but are characterised instead by a certain degree of roughness. In contrast to filler particles such as silver flakes or coated balls, which usually only produce one-dimensional contacts with the raised portions, increasing the contact resistance as a result and weakening the contact, especially with regard to strong current, a connection structure is provided with the carbon nanotube macrostructures according to the invention that has a conductance superior by several orders of magnitude to standard materials in respect of current densities. The exceptionally finely structured, fibre-like geometry of the carbon nanotubes is particularly advantageous with regard to contact geometry. Due to their flexibility, the carbon nanotubes can hug the surface contours and lie in the microscopic gaps, which leads to multidimensional contacts and to a significantly larger effective area of contact. Owing to the structure of the macrostructures, a rough surface may project into the macrostructure such that the potential contact area is increased by a multiple factor.

It should be understood, as a basic principle, that the matrix material is usually applied in a liquid form to the adherends, but in certain applications it is also advantageous to apply it in solid form, for example as a film. The viscosity and wetting ability of the adhesive, which is immanently affected by the viscosity of the matrix material and by the size, structure and concentration of the macrostructures therein, also indirectly by external factors such as temperature and pressure, can preferably be adjusted such that the adherends are completely covered and that the adhesive also penetrates into small structures of the components to be bonded. The intention is that the adhesive can be transitioned to a cured state to achieve the bonded state. The adhesive can basically be cured in a chemical reaction or by physical setting; a reactive hot-melt adhesive can also be deployed. “Curable” should be understood as a characteristic of the adhesive to transition into a state in which mechanical loads can be transmitted through the adhesive. In that state, the adhesive may be elastic or substantially stiff.

As a basic principle, the electrically conductive adhesive according to the invention is characterised in that it contains macrostructures which for their part are composed of a plurality of carbon nanotubes and interspersed by the matrix material. Any boundary surface problems are thus avoided due to the macrostructures in the adhesive, as the macrostructures are present inside the matrix material in an ideally integrated form, and because the flow of mechanical forces has only a minor effect and acts, more specifically, as fibre reinforcement. For these reasons, delamination or mechanical failure due to the macrostructures cannot occur in the adhesive according to the invention, or only to a much smaller extent than in prior art adhesives. Due to the presence of the macrostructures in a specific concentration, the electrically conductive adhesive also provides an advantageous, anisotropic electrical conductivity and can therefore be used to connect electrical contacts, which are discretely spaced apart in insulated form from other, electrically to other electrical contacts which are likewise discretely spaced apart in insulated form from other on a second adhesive surface.

It should be understood as a basic principle in this context that the adhesive according to the invention preferably consists of the matrix material and the macrostructures containing carbon nanotubes, and that a surface coating of the macrostructures or the carbon nanotubes is dispensed with in order to thus exploit in an optimal manner the potential of the materials used, not only with regard to their mechanical properties, but also with regard to their electrical properties.

According to a first preferred embodiment, the macrostructures are present with a substantially spherical geometry, and the values for the height, width and length of any macrostructure do not deviate in any of the values by more than 50% from any one of the other values. This promotes anisotropic conductivity, in that there is no conductivity in the direction of the adhesive surface plane, yet conductivity is provided orthogonally through that plane. By means of macroparticles that are geometrically shaped in this manner, the macrostructures in the inventive adhesive are ideally provided in a spherical shape or in a shape which deviates from that ideal shape to a certain degree only. It should be understood as a basic principle in this regard that there is preferably no difference or only very little difference between the length, the height and the width of a particle, i.e. the particle approaches an elongation of zero and a circularity of 1. This development of the invention renders the contact characteristics of the macrostructures independent of their alignment within the matrix material. It should also be understood as a basic principle in this context that the macrostructures deviate from each other in their geometrical dimensions as little as possible, i.e. the standard deviation of the measured length, width and/or height, or the values characterising the overall size, such as diameter, cross-sectional area or total volume of a macrostructure, is as small as possible over a large number of measured macrostructures, thus resulting in a monomodal size distribution of the macrostructures with a pronounced maximum for a particular macrostructure size and only a small percentage of macrostructures that are larger or smaller in size. Such a distribution permits reliable adhesive bonding and electrical contacting with a low reject rate due to the adhesive according to the invention, in that the electrical contacting can be produced in a reproducible manner with predetermining process parameters by the defined macrostructures. If, for example, a limited degree of anisotropy in the adhesive surface is intended, for example to connect contacts which are arranged in pairs and with a short distance between each other, but not to connect the two members of the pair to each other, then a multimodal distribution may be desirable.

The adhesive according to the invention is used for a typical adhesive gap thickness of 10 to 70 μm, the adhesive gap thickness being understood here as the average distance between the two electrically contacting surfaces that are bonded together, in their finished, bonded state. The macrostructures may be present in a concentration of up to 40 vol.-%, preferably 10 to 20 vol.-%. Each macrostructure has maximum dimensions of one to three times the adhesive gap thickness, preferably from 1.1 times to two times the adhesive gap thickness. In particular cases, the maximum dimensions may also be less than the adhesive gap thickness, for example in the range from 0.5 to 0.9 times the adhesive gap thickness. These special cases require a special measure in order to produce an agglomeration of two or a few macrostructures in the region of the electrically contacting surfaces, despite their concentration below the percolation threshold.

It is also preferred that the macrostructures are present in a form that is achieved by shearing a fluid comprising carbon nanotubes distributed therein, in particular by at least a first shearing of the fluid in a first direction, followed by a second shearing in a second direction which is different from the first direction and in particular is non-parallel or anti-parallel to the first direction. The invention is essentially based on the realisation that the agglomeration of carbon nanotubes to form macrostructures can result in an electrically conductive adhesive having an advantageous design and better properties. This agglomeration is advantageously produced by shearing in at least one direction. By performing such shearing, a macrostructure can typically be produced that has a pronounced axial orientation transverse to the direction of shear. In one advantageous configuration in this respect, the macrostructure is produced by an additional second shearing in a direction different from that of the first shearing. In this way, the macrostructures produced by the first shearing can either be reshaped or further agglomerated as macrostructures with a geometry which deviates from the elongate structure and tends more to the ideal spherical shape. As a basic principle, shearing can also be performed by arranging the matrix material containing carbon nanotubes between two surfaces, by first moving these surfaces in a first direction relative to one another and then moving them in a second direction relative to one another. This can be implemented, for example, by rotating a cylinder inside a pipe coaxial therewith, followed by axial displacement of the cylinder inside the pipe, the carbon nanotubes being arranged in the annulus between the pipe and the cylinder, or by other tooling designs. The adhesive according to the invention is essentially characterised, in the case of one-dimensional shearing, by elongatedly extending macrostructures, and in the case of two-dimensional shearing by shorter macrostructures approximating to the spherical shape.

It is still further preferred that the carbon nanotubes are present in the matrix material in a concentration below the percolation threshold of the carbon nanotubes in the matrix material. It should be understood, as a basic principle, that the carbon nanotubes in the matrix material may be present below or above or exactly on the percolation threshold and that agglomeration can be achieved by mechanical means or induced in some other way. However, to achieve a particularly advantageous electrical conductivity, it is particularly advantageous to introduce the carbon nanotubes in such a concentration that they would already provide an isotropic conductivity of the adhesive by themselves, which is then modified by the formation of macrostructures to obtain anisotropic conductivity. The carbon nanotubes may tend to agglomerate without any external effects playing a role, and this agglomeration can then be controlled in such a way, with additional external effects if necessary, for example by mechanical shearing in one or two directions as described in the foregoing, that advantageously shaped macrostructures are formed by such agglomeration. An electrically conductive adhesive is obtained in this way, which, while not having any tendency on the part of the macrostructures to agglomerate in the absence of external influences, comprises macrostructures in such a concentration and having, within the macrostructures, such an amount and density of carbon nanotubes, that the adhesive is electrically conductive, and the adhesive and cohesive effect of the adhesive is achieved in an ideal manner.

In certain applications, however, it is also advantageous to provide the carbon nanotubes in a concentration which is below the percolation threshold in the matrix material. Although the adhesive without macrostructures has no electrical conductivity in that case, formation of the macrostructures makes the adhesive anisotropically electrically conductive.

It is still further preferred that a macrostructure contains at least one substance, in particular a magnetic element, which is functionally effective in bonding to a joining surface region. With the adhesive according to the invention, anisotropic electrical connecting can be achieved purely by providing the macrostructures in the appropriate size and defined concentration. The adhesive can be processed in such a way that it achieves sufficient electrical connecting of electrical conductor structures of defined configuration on two components, on the basis of a statistical distribution of the macrostructures in the adhesive. More particularly, however, it is preferred that the macrostructures be doped with a functional element or a plurality of such functional elements, which bring about a specific deposition of the macrostructures on a joining surface region to be connected electrically. To achieve this purpose, the joining surface region can also be treated mechanically, chemically or physically in a specific manner in order to bring about or promote this specific deposition of the macrostructures. More particularly, a magnet can be deployed between the macrostructure and the joining surface region to be connected electrically, and other effects, such as chemical affinity, electrostatic effects or the like can also be instilled, in the form of a functional element, in the macrostructures.

Another aspect of the invention relates to a method of producing an electrically conductive adhesive, the method comprising the steps of
a. supplying an auxiliary production matrix,
b. introducing carbon nanotubes into the auxiliary production matrix,
c. agglomerating the carbon nanotubes to form macrostructures within the auxiliary production matrix, and
d. distributing the macrostructures in a polymeric adhesive matrix in a concentration below the percolation threshold of the macrostructures in the adhesive mass.

According to this inventive method, an electrically conductive adhesive consisting of at least two starting materials in two phases is produced. A first phase is an adhesive matrix which can be brought from a normally liquid state to a hardened state by curing and which then, in this cured state, exerts adhesive forces on the joining surface and can transmit cohesive forces which are required to bond the two components to be joined. The second phase consists of carbon nanotubes which have agglomerated to form macrostructures and which are present in distributed form in this adhesive matrix in such a concentration that these macrostructures do not percolate in the absence of external influences. The macrostructures can basically be produced in an auxiliary production matrix which is chemically different from the adhesive matrix, or which is chemically identical to the latter, for example, or which has a different or identical concentration on the whole. The auxiliary production matrix preferably has a lower viscosity than the adhesive matrix, in order to promote the formation of macrostructures from the carbon nanotubes. Once the macrostructures have formed in the auxiliary production matrix, they can be introduced into the adhesive matrix and finely distributed therein in order to produce the ideal state for processing the adhesive being produced.

The macrostructures may be formed in the adhesive matrix even before the adhesive is introduced into the adhesive gap, or their formation may be delayed until the joining process after the adhesive has been introduced into the adhesive gap.

The method may be developed by performing the following steps between steps c and d:
extracting the macrostructures from the auxiliary production matrix, preferably by distillation, and
introducing the macrostructures into the adhesive matrix, the adhesive matrix having a chemical composition different from that of the auxiliary production matrix.

Whereas the macrostructures together with the auxiliary production matrix can basically be introduced into the adhesive matrix, the auxiliary production matrix thus becoming either a component of the adhesive or being subsequently removed from the adhesive in a later step of the process, this development of the invention advantageously requires that the macrostructures be insulated from the auxiliary production matrix after they have been produced therein. This insulation can specifically be achieved by distillation, the auxiliary production matrix being converted to a gaseous state by heating it, the macrostructures being left behind in an insulated, solid form as a result. This extraction of the macrostructures from the auxiliary production matrix is particularly advantageous whenever the auxiliary production matrix and the adhesive matrix have different chemical compositions, or at least have different concentrations and hence viscosities. This opens up the possibility of selecting an auxiliary production matrix which is ideally suited to the step of producing the macrostructures, and of introducing the macrostructures produced in that step into an adhesive matrix which is ideally suited for the desired adhesive effect.

Alternatively, the auxiliary production matrix may be chemically identical to the adhesive matrix, and the concentration of the macrostructures after step c can be increased if need be by distillation, or be decreased by adding adhesive matrix. In this variant of the method, which involves process engineering that is simpler and more economical than the variants described above, involving extraction of the macrostructures from the auxiliary production matrix, an adhesive matrix is used that is already suitable for the subsequent adhesive action and the viscosity of which is merely brought to an ideal value for formation of the macrostructures, by thinning or concentrating it as required. Once the macrostructures have been produced, an ideal viscosity for processing the adhesive can then be set, either by distillation with subsequent removal of adhesive matrix portions, or by thinning the adhesive by adding adhesive matrix portions.

It is still further preferred that the carbon nanotubes in step c. are agglomerated to form the macrostructures by introducing a shear into the auxiliary production matrix, in particular by successive shearing in two different directions, preferably with simultaneous application of compressive forces. This development of the invention makes production of the macrostructures particularly efficient. Reference is made to the description in the foregoing for the specific design of the shearing operation and its specific implementation.

It is still further preferred that the agglomeration of the carbon nanotubes in step c. is supported by reducing the viscosity of the auxiliary production matrix, in particular by heating. It has basically been found that the desired agglomeration of the carbon nanotubes to form macrostructures having a geometry which is good for electrical connecting is specifically achieved with a high level of reproducibility and with good results when the auxiliary production matrix has a low viscosity. To achieve this, heat may also be applied, which causes a significant reduction in viscosity in normal auxiliary production matrixes, and a favourable viscosity for processing the adhesive can be obtained again by allowing it to cool down.

It is still further preferred that the carbon nanotubes are introduced into the auxiliary production matrix in step b. in a concentration higher than the percolation threshold of the carbon nanotubes in the auxiliary production matrix. As a basic principle, the carbon nanotubes must be introduced into the auxiliary production matrix, in the method according to the invention, in such a concentration that agglomeration can be effected either by external influences, or without such external influences, i.e. the concentration is above the percolation threshold of the carbon nanotubes in the auxiliary production matrix. In the latter case, the auxiliary production matrix is loaded to an ideal, high level, thus allowing efficient production of the macrostructures. It should be understood in this regard that the macrostructures themselves may be present in the auxiliary production matrix below the percolation threshold once they have been produced, i.e. in the absence of external influences, there is no agglomeration of the macrostructures to form even larger structures.

Another aspect of the invention relates to a method for electrically conductive bonding of two components, the method comprising the steps of
a. supplying an adhesive comprising an adhesive matrix formed from an adhesively acting material and a plurality of carbon nanotubes,
b. introducing the adhesive into at least one joining surface of one of the two components to be joined,
c. joining the two component in such a way that the joining surface of the one component is placed onto the joining surface of the other component and an adhesive gap forms between these two joining surfaces,
   wherein the thickness of the adhesive gap, at least in those sections of the adhesive gap lying between two opposite regions of the joining surface, between which an electrically conductive connection is to be produced from the joining surface region of the one component across the adhesive gap section to the joining surface region of the other component, is less than or equal to a dimension of a macrostructure which is formed of a plurality of the carbon nanotubes and is present in the adhesive matrix,
d. forming an electrical connection by means of carbon nanotube macrostructures in sections of the adhesive gap lying between regions of the joining surface that have electrically conductive regions of the joining surface regions facing towards the adhesive gap and towards each other, and which are to be electrically connected to each other via said regions,
e. curing of the matrix material.

With the method according to the invention, a mechanical connection is formed due to adhesive effects between an adhesive and the joining surfaces of two components, and due to cohesive transmission of forces within the adhesive, and in the process an anisotropic electrical connection between electrically conductive joining surface regions is simultaneously established. An anisotropic electrical connection is understood in this context to be an electrical connection between two typically opposite electrical points of contact on the one component and on the other component, which allows a flow of current in a first direction, but which does not allow any flows of electric charge in a second direction relative thereto and preferably in any other directions relative thereto, but instead is insulated against such flows of current. In other words, the anisotropic electrical connections consists in a channelled, outwardly shielded connection between two discretely defined contacts.

According to the invention, this anisotropic electrical connection is achieved by providing an adhesive containing macrostructures formed from agglomerated carbon nanotubes, and by disposing this adhesive in an adhesive gap. The thickness of the adhesive gap, at least in those sections of the adhesive gap which are provided for an anisotropic electrically conductive connection, is less than or equal to a dimension of the macrostructures, according to the invention. A dimension is understood in this context to be a height, a width or a length of the macrostructures, and more specifically, if the macrostructures approximate to the spherical shape which is especially suitable for performing the method according to the invention, a diameter of the macrostructures. It can basically be assumed in this regard that, when the dimensions of the plurality of macrostructures are distributed within a particular range, the inventive method is performed on the basis of an averaged dimension, but in alternative embodiments it is also advantageous to base the dimension on a lower or upper limit as a minimum or maximum value instead of the averaged dimension, and to adjust the thickness of the adhesive gap accordingly.

Due to the specific relationships between the adhesive gap thickness and the dimensions of the macrostructures, a macrostructure disposed between the two joining surfaces comes into direct contact with the joining surfaces, at least in those areas that are to be connected to each other electrically, thus establishing an electrical connection. Once this electrical connection has been produced by bringing closer together the two components to be joined, the adhesive bond can then be produced by curing of the matrix material, thus fixing the mechanically and electrically connected state thus produced.

It is particularly preferred in this regard that the joining surfaces are planar and that the distance between a first joining surface region on one component and a second joining surface region on the same component, which are both to be electrically connected across respective sections of the adhesive gap to respective joining surface regions on the other component, is larger than any one of the dimensions of the macrostructures, in particular larger than the largest dimension of the macrostructures, such that the adhesive gap section between the first joining surface region and its opposite joining surface region on the other component is electrically insulated from the adhesive gap section between the second joining surface region and its opposite joining surface region on the other component. According to this development of the invention, a plurality of joining surface regions on one component are electrically connected to a respective plurality of joining surface regions on the other component, each single one of these electrical connections being insulated inside the adhesive from the other electrical connections. This electrical insulation is achieved by selecting an appropriate geometry, the gap between two adjacent joining surface regions on one component being selected larger than a dimension of, in particular than the largest dimension of the macrostructure, in order to prevent a macrostructure which contacts a joining surface region with electrical contact from extending laterally to such an extent that it simultaneously forms an electric contact to the other joining surface region or to a macrostructure disposed thereon and in electrical contact therewith. In one specific embodiment, in which the macrostructures approximate to the spherical shape ideal for performing the inventive joining method, the development of the invention may be configured in such a way that the gap between two adjacent joining surface regions to be insulated from each other on one component is larger than the diameter of the macrostructures.

It is still further preferred that at least one adhesive gap section between opposite joining surface regions to be electrically connected to each other has a smaller thickness than an adhesive gap section between opposite joining surface regions, between which no electrical connection is to be formed across the adhesive gap. This embodiment is an alternative to, or a development of the previously described development of the invention and allows on the whole a more dense arrangement of adjacent joining surface regions to be insulated from each other on one component. This is achieved by those joining surface regions, which are to be exposed to an electrical connection, entering into an electrical connection with each other across an adhesive gap which is less thick than regions in which no such electrical connection is to be effected. This development of the invention reduces the risk of a connection being established, due to deposition of macrostructures on joining surface regions that are not to be electrically connected, between two joining surface regions that are to be insulated from each other, in that the ratio of the size of the macrostructures to the thickness of the adhesive gap is reduced in these joining surface regions that are not to be connected electrically to each other.

It is particularly preferred that the smaller thickness of the adhesive gap between the two opposite joining surface regions to be electrically connected to each other is produced by at least one of the two joining surface regions being raised in relation to the surrounding joining surface regions of the same joining surface. According to this embodiment, a three-dimensional structure of at least one joining surface region, and preferably of both joining surface regions, is obtained by applying appropriate technologies, wherein the joining surface regions to be electrically connected are raised in relation to the joining surface regions that are not to be connected electrically. This is realised in such a way, for example, that electrical points or lines of contact protrude out of the joining surface region and project as a result into the adhesive gap, and that when the joining surfaces come closer together until they are a particular distance apart, a thinner adhesive gap is formed between these raised structures than between the non-raised structures.

It is still further preferred that a hook, thorn or bristle structure is formed on at least one joining surface region, said structure being able to form a form-locking connection with a macrostructure, and the electrical connection being formed by flushing the adhesive gap with the adhesive and mechanically attaching a macrostructure to the hook structure. As a basic principle, the inventive joining method can be performed with one or a plurality of functional elements being present in the macrostructures, which effect or promote deposition on the joining surface regions to be electrically connected. Reference is made in this regard to the above description of the respectively embodied adhesive. More particularly, a thorn structure may be provided which can cause a latching effect in a direction of movement parallel to the joining surface, thus causing macrostructures, which flow over the joining surfaces to be electrically connected when adhesive is being flushed through the adhesive gap, to attach themselves to said joining surface. In an alternative or additional configuration, the targeted deposition of the macrostructures on joining surface regions to be electrically connected may be achieved by mechanical clamping, hooking, jamming or in some other way, by forming on the joining surface region to be electrically connected a suitable structure that is adapted for appropriate attachment of the macrostructures thereto.

According to one other development of the joining method according to the invention, the matrix material is cured by the action of a direct current or eddy current on the adhesive in the adhesive gap. By configuring numerous anisotropic electrical connections within the adhesive gap from the one component to the other component, the matrix material can be cured not only by known curing methods, such as chemical curing by a two-component matrix material, or photo-induced curing, or by the reaction of one component with the surroundings, in particular with ambient air, but also, more specifically, by means of the heat produced by an eddy current. The appropriate eddy current can be induced, more specifically, by a magnetic field acting on the adhesive gap.

A further aspect of the invention, finally, relates to a method for checking the quality of an adhesive bond produced according to the joining method described in the foregoing, said method being characterised in that the electrical resistance between different points of a component, or between the one and the other component, is measured under the influence of a mechanical strain on the joint, that the ratio of the electrical resistance, the impedance or the admittance to the strain is compared with predetermined values, in particular with values obtained from preceding measurements performed on such adhesive connections, or with values which characterise the ratio or the curve, and/or with absolute values calculated from geometrical or electrical properties, and that, if the ratio varies beyond a particular tolerance range, or discontinuities occur in the resistance-strain curve, the adhesive bond is inferred to have partially failed.

This method for checking quality is made possible by the specific anisotropic electrical connection between the two components that is obtained with the inventive joining method, in that the discrete electrical connection produced at a plurality of points, which in turn are electrically insulated from each other, is used to measure the resistance across the adhesive gap. The invention exploits the fact that the electrical connection formed by the carbon nanotube macrostructures changes its electrical resistance across the adhesive gap when a mechanical strain is applied to the adhesive gap, or if tears occur, and if it is possible, when measuring the electrical resistance, to distinguish by means of the strain applied between the effects caused, namely the change in resistance produced by the strain when an adhesive and cohesive connection across the adhesive gap exists and is intact, compared to separation caused by local, partial delamination of a macrostructure from a joining surface region, or failure within the adhesive due to the permissible cohesive tension being exceeded. The macrostructures according to the invention basically exhibit a proportional increase in their electrical resistance when placed under a mechanical strain. However, if delamination or cohesive fractures occur, then these are manifested by a sudden increase in the resistance, which is then characterised by inconsistencies or discontinuities, and by a greater increase in resistance, measured under strain, that results from the sum of such delamination.

One specific application of the adhesive according to the invention is for electromagnetic or electrostatic shielding. The type of carbon nanotubes, the concentration of carbon nanotubes in each macrostructure, the concentration of the macrostructures in the array and the shape and size of the macrostructure can all be selected according to the wavelength or wavelength ranges of the electromagnetic radiation against which shielding is to be provided. For example, the shape and size of the macrostructures can preferably be equal to the wavelength or to an integer multiple of one half of the wavelength. The invention shall now be explained in greater detail with reference to preferred embodiments and the Figures, in which:

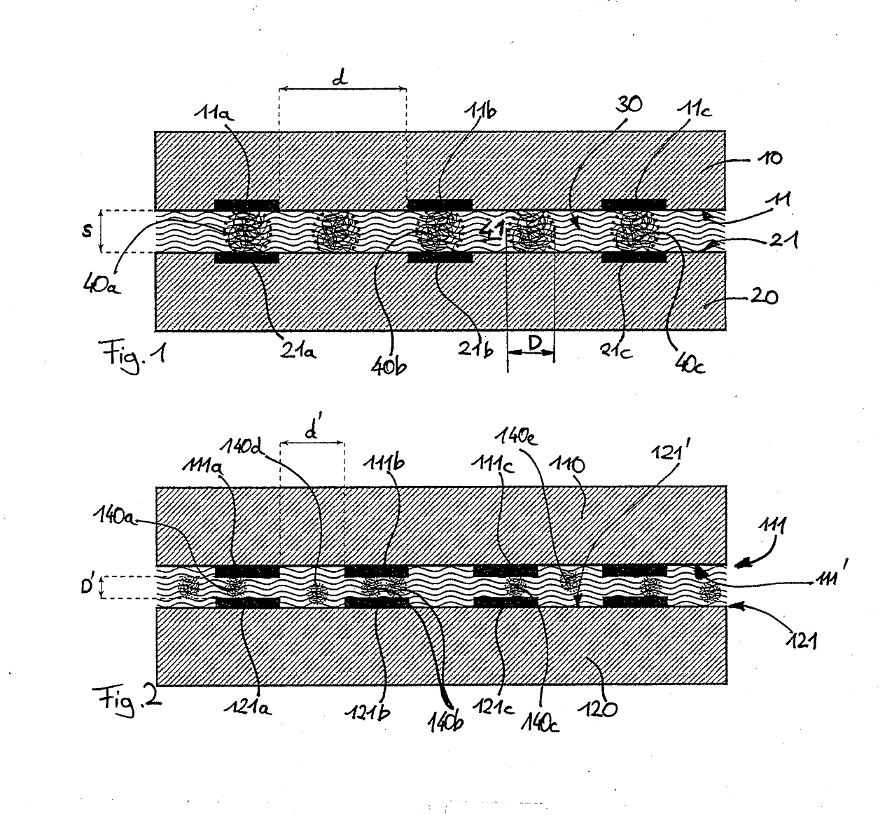

FIG. 1 shows a schematic, cutaway side view of a first embodiment of the invention, and

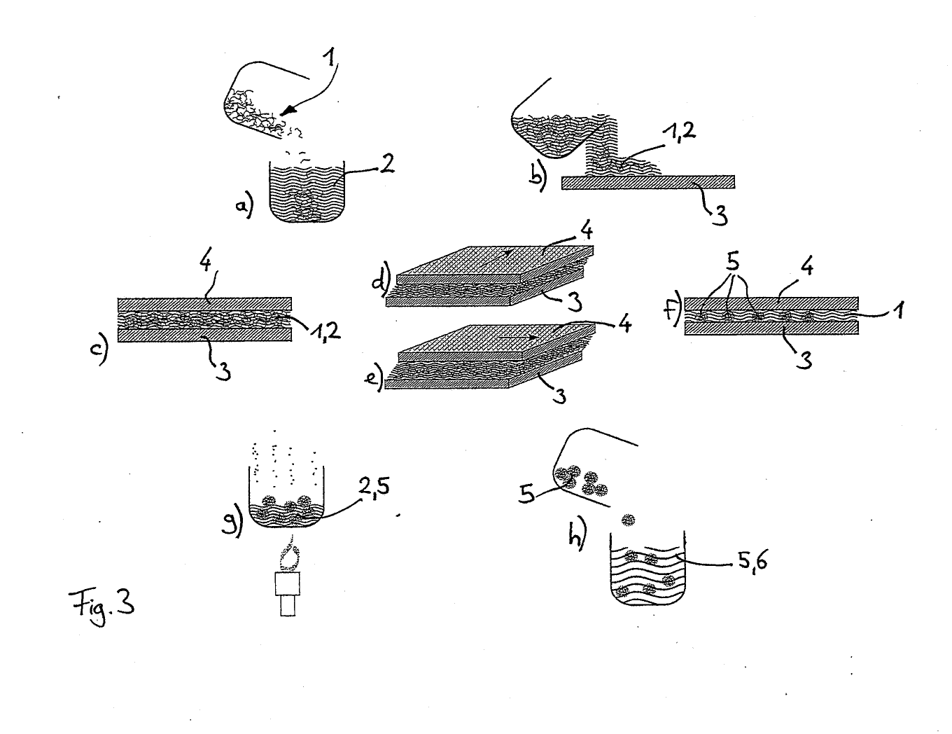

FIG. 2 shows a schematic, cutaway side view of a second embodiment of the invention, and

FIG. 3 shows a schematic view of the production process for an adhesive according to the invention.

As can be seen from FIG. 1, two components which are to be bonded together and between which an anisotropic electrical connection is to be formed in the process across the adhesive gap are arranged in such a way that the joining surface region 11 of the first component 10 is arranged opposite the joining surface region 21 of a second component 20. An adhesive gap 30 is formed between the two joining surfaces 11, 21.

Electrically conductive joining surface regions 11a, b, c are formed in the first joining surface 11. These joining surface regions 11a, b, c lie opposite respective joining surface regions 21a, b, c that are formed on the second joining surface 21. Joining surface regions 11a-c lie in a plane with the joining surface 11, and in the same manner joining surface regions 21a-c lie in a plane with joining surface 21. The gap d between two adjacent joining surface regions 11a-c or 21a-c is larger than the diameter of a macrostructure 40a-c disposed in adhesive gap 30.

Macrostructures 40a, b, c consist of a plurality of agglomerated carbon nanotubes and are agglomerated to form a spherical shape having a diameter D2. Macrostructures 40a-c are surrounded by an adhesive matrix 41, which has attached itself with an adhesive force to joining surface 11, 21 in the region between joining surface regions 11a-c and 21a-c, thus forming an adhesive bond. The adhesive matrix may be an adhesive from the group of chemically reactive adhesives, i.e. a cold curing or hot curing polycondensation, polymerisation or polyaddition adhesive. An epoxy resin is preferably used as adhesive matrix.

Macrostructures 40a-c are in contact with joining surface regions 11a-c and 21a-c and connect joining surface regions 11a, 21a and 11b, 21b and 11c, 21c in this manner. The diameter D of the macrostructures is greater than the adhesive gap thickness s and smaller than gap d. This ensures that an electrical contact via macrostructures 40a-c is achieved by direct deposition on joining surface regions 11a-c, 21a-c, and at the same time that, in the longitudinal direction of the adhesive gap, no electrical connection is produced by one macrostructure 40a being able to form an electrical connection with an adjacent macrostructure 40b.

As can be seen from FIG. 2, joining surface regions 111a-c and 121a-c which are raised in relation to unraised surface areas 111′ and 121′ may be provided in this embodiment on joining surfaces 111, 121. As a result, the adhesive gap that exists between two surface regions to be electrically connected to each other is reduced to a small amount when components 110, 120 are brought closer together, and an electrical connection through macrostructures 140a-c is achieved. Macrostructures 140a-c have a dimension which prevents the risk of any undesired electrical connection being formed transversely between adjacent joining surface regions 111a-c on the one component 110 or 121a-c on the other component 120, even when macrostructures 140d, e are disposed in these insulating intermediate regions within the adhesive matrix. In this way, it is possible to achieve an electrical connection with a finer structure on the whole.

FIG. 3 shows a preferred method of producing the inventive adhesive. In the first step of the method, a) a number of carbon nanotubes 1 are introduced into an auxiliary production matrix 2, the carbon nanotubes 1 in auxiliary production matrix 2 reaching a concentration that is above the percolation threshold. The agglomeration of the carbon nanotubes to form larger agglomerates, which then occurs without external influences being required, is controlled by shearing the auxiliary production matrix, with the carbon nanotubes distributed therein, in such a way that macrostructures with an advantageous geometry for the desired effect of the adhesive ensue. This shearing is effected by the auxiliary production matrix, along with the carbon nanotubes distributed therein, being disposed between two surfaces 3, 4, b), c) and these surfaces being moved relative to each other in a first direction in a first step d), and, in a second step e), being moved in a second direction relative to one another.

As a result of these two successive shearings of the auxiliary production matrix in two different directions, macrostructures are produced that approximate in large part to the ideal spherical shape and thus have a circularity close to 1.

The macrostructures 5 obtained in this manner are now present f) in a concentration in the auxiliary production matrix 2 that is below the percolation threshold, i.e. macrostructures 5 are dispersed in auxiliary production matrix 2, are not connected electrically to each other and show no tendency to agglomerate to form larger macrostructures.

In a further production step g), the macrostructures 5 formed in this manner are now extracted by distillation from auxiliary production matrix 2 and are now present in a free-flowing form. The macrostructures are then h) introduced into an adhesive matrix 6, in a concentration that is below the percolation threshold, as a result of which they can disperse in finely distributed form within the adhesive matrix.

Depending on how the liquid adhesive matrix is to be hardened or cured, the macrostructures may be introduced into only one of two components of the adhesive matrix or into both components of the adhesive matrix, and the two components can then be mixed together just before they are processed, in order to trigger a delayed chemical reaction resulting in curing of the adhesive matrix. In other variants, in which curing of the adhesive matrix is photo-induced, heat-induced, or induced by reaction with ambient air or the like, a single-component adhesive matrix is used instead, and curing of the adhesive matrix is induced accordingly, as soon as it has distributed itself in the adhesive gap in the desired manner.

1. An electrically conductive adhesive, comprising
an adhesively acting and electrically non-conductive or weakly conductive matrix material (6; 41), preferably of a polymer material or a polymerisable material, and
a phase of electrically conductive carbon nanotubes (1) distributed in the matrix material,
characterised in that the carbon nanotubes are present in a plurality of individual macrostructures (40a-c; 140a-c; 5), that each macrostructure consists of a plurality of agglomerated carbon nanotubes forming electrical contact among each other, and that the macrostructures are present in the matrix material in a concentration that is lower than the percolation threshold of the macrostructures within the matrix material.

2. The adhesive according to claim 1,
characterised in that the macrostructures are present with a substantially spherical geometry and that the values for the height, width and length of any macrostructure does not deviate in any of the values by more than 50% from any one of the other values.

3. The adhesive according to claim 1,
characterised in that the macrostructures are present in a form that is achieved by shearing a fluid comprising carbon nanotubes distributed therein, in particular by a first shearing of the fluid in a first direction, followed by a second shearing in a second direction different from the first direction.

4. The adhesive according to claim 1,
characterised in that the carbon nanotubes are present in the matrix material in a concentration below the percolation threshold of the carbon nanotubes in the matrix material.

5. The adhesive according to claim 1,
characterised in that at least one element adapted to be functionally effective for bonding with a joining surface region, in particular a magnetic element, is present in a macrostructure.

6. A method of producing an electrically conductive adhesive, comprising the steps of
a. supplying an auxiliary production matrix (2),
b. introducing carbon nanotubes (1) into the auxiliary production matrix,
c. agglomerating the carbon nanotubes to form macrostructures (5) within the auxiliary production matrix, and
d. distributing the macrostructures in a polymeric adhesive matrix (6) in a concentration below the percolation threshold of the macrostructures in the adhesive mass.

7. The method according to claim 6,
characterised in that the following steps are performed between steps c and d:
extracting the macrostructures (5) from the auxiliary production matrix (2), preferably by distillation, and
introducing the macrostructures (5) into the adhesive matrix (6),

8. The method according to claim 6,
characterised in that the auxiliary production matrix (2) is chemically identical to the adhesive matrix (6) and that the concentration of the macrostructures after step c is increased if need be by distillation, or is decreased by adding adhesive matrix.

9. The method according to claim 6,
characterised in that the carbon nanotubes in step c. are agglomerated to form the macrostructures by introducing a shear into the auxiliary production matrix, in particular by successive application of shear forces in two different directions, preferably with simultaneous application of compressive forces.

10. The method according to claim 6,
characterised in that the agglomeration of the carbon nanotubes in step c. is supported by reducing the viscosity of the auxiliary production matrix, in particular by heating.

11. The method according to claim 6,
characterised in that the carbon nanotubes are introduced into the auxiliary production matrix in step b. in a concentration higher than the percolation threshold of the carbon nanotubes in the auxiliary production matrix.

12. A method for electrically conductive bonding of two components (10, 20), the method comprising the steps of
a. supplying an adhesive (41, 40a,b,c), comprising an adhesive matrix (41) formed from an adhesively acting material and a plurality of carbon nanotubes,
b. introducing the adhesive into at least one joining surface (21) of one of the two components to be joined,
c. joining the two component in such a way that the joining surface (11) of the one component is placed onto the joining surface (21) of the other component and an adhesive gap (30) forms between these two joining surfaces,
wherein the thickness (s) of the adhesive gap, at least in those sections of the adhesive gap lying between two opposite regions of the joining surface, between which an electrically conductive connection is to be produced from the joining surface region of the one component across the adhesive gap section to the joining surface region of the other component, is less than or equal to a dimension (D) of a macrostructure (40a,b,c) which is formed of a plurality of the carbon nanotubes and is present in the adhesive matrix (41),
d. forming an electrical connection by means of carbon nanotube macrostructures in sections of the adhesive gap lying between regions of the joining surface that have electrically conductive regions of the joining surface regions (11a-c, 21a-c) facing towards the adhesive gap and towards each other, and which are to be electrically connected to each other via said regions,
e. curing of the matrix material.

13. The method according to claim 12,
characterised in that the joining surfaces (11, 21) are planar and that the distance (d) between a first joining surface region (11a) on one component (10) and a second joining surface region (11b) on the same component, which are both to be electrically connected across respective sections of the adhesive gap to respective joining surface regions on the other component, is larger than any one of the dimensions (D) of the macrostructures (40a-c), in particular larger than the largest dimension of the macrostructures, such that the adhesive gap section between the first joining surface region and its opposite joining surface region on the other component is electrically insulated from the adhesive gap section between the second joining surface region and its opposite joining surface region on the other component.

14. The method according to claim 12,
characterised in that at least one adhesive gap section between opposite joining surface regions (111a, 121a) to be electrically connected to each other has a smaller thickness than an adhesive gap section between opposite joining surface regions (111′, 121′), between which no electrical connection is to be formed across the adhesive gap.

15. The method according to claim 14,
characterised in that the smaller thickness of the adhesive gap between the two opposite joining surface regions to be electrically connected to each other is produced by at least one of the two joining surface regions (111a-c, 121a.c) being raised in relation to the surrounding joining surface regions (111′, 121′) of the same joining surface.

16. The method according to claim 12,
characterised in that a surface structure is formed on at least one joining surface region, said surface structure being able to form a form-locking connection with a macrostructure, and the electrical connection being formed by flushing the adhesive gap with the adhesive and mechanically attaching a macrostructure to the surface structure.

17. The method according to claim 12,
characterised in that the matrix material is cured by the action of a direct current or eddy current on the adhesive in the adhesive gap.

18. A method for checking the quality of an adhesive bond produced by a method according to claim 12,
characterised in that the electrical resistance, the impedance or the admittance between different points of a component, or between the one (10) and the other component (20) is measured under the influence of a mechanical strain on the joint, that the ratio of the electrical resistance to the strain is compared with predetermined values and that, if the ratio varies beyond a particular tolerance range, or discontinuities occur in the resistance-strain curve, the adhesive bond is inferred to have partially failed.
